(19) United States
(12) Patent Application Publication
(10) Pub. No.: US 2017/0193885 A1
(43) Pub. Date: Jul. 6, 2017

(54) SHIFT REGISTER UNIT, DRIVING METHOD, GATE DRIVING CIRCUIT AND DISPLAY DEVICE

(71) Applicants: BOE TECHNOLOGY GROUP CO., LTD., Beiing (CN); HEFEI BOE OPTOELECTRONICS TECHNOLOGY CO., LTD., Anhui (CN)

(72) Inventors: Silin FENG, Beijing (CN); Hongmin LI, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/198,674

(22) Filed: Jun. 30, 2016

(30) Foreign Application Priority Data
Jan. 4, 2016 (CN) 201610004051.0

(51) Int. Cl. G09G 3/20; G11C 19/28

(52) U.S. Cl. CPC G09G 3/2092; G11C 19/28; G09G 2310/0286; G09G 2310/0202; G09G 2300/0809

(57) ABSTRACT

The present disclosure provides a shift register unit, a driving method, a gate driving circuit and a display device. The shift register unit includes a pull-up transistor; a storage capacitor; an output noise reduction transistor; a pull-down node control module, which controls a pull-down node to be at a first low level or a first high level under the control of the pull-up node; a pull-up node control module, which controls the pull-up node to be or not to be at a second high level under the control of an input signal and controls the pull-up node to be at or not to be at a second low level under the control of a reset signal; and a pull-up node noise reduction module, which controls the pull-up node to be or not to be at the first low level under the control of the pull-down node.

### CROSS-REFERENCE TO RELATED APPLICATION

This application claims a priority to Chinese Patent Application No. 201610004051.0 filed on Jan. 4, 2016, which is incorporated herein by reference in its entirety.

### TECHNICAL FIELD

The present disclosure relates to the field of the display technology, in particular to a shift register unit, a driving method, a gate driving circuit and a display device.

### BACKGROUND

FIG. 1 shows a circuit diagram of a 4T1C shift register unit in related arts. As shown in FIG. 1, the shift register unit includes a first transistor M1, a second transistor M2, a third transistor M3, a fourth transistor M4 and a storage capacitor C1, wherein a reference sign “PU” indicates a pull-up node, a reference sign “Input” indicates an input end, a reference sign “CLK” indicates a clock signal input end, a reference sign “Output” indicates an output end for outputting a gate electrode driving signal, a reference sign “Reset” indicates a reset end, and a reference sign “VGL” indicates a first low voltage level.

As shown in FIG. 2, when the shift register unit shown in FIG. 1 is operating,

at a first stage t1, the input end outputs a high level, both the CLK and the Reset end output low levels, so that the second transistor M2 and the fourth transistor M4 are turned off and the first transistor M1 is turned on; when the first transistor M1 is turned on, the pull-up node PU is at the high level; at this time, the third transistor M3 is turned on;

at a second stage t2, the input end outputs a low level, so that the first transistor M1 is turned off, due to the function of C1, the level of the pull-up node PU is kept at the high level, and the third transistor M3 is turned on; when the CLK outputs the high level, the output end outputs the high level;

at a third stage t3, both the input end and the CLK output the low levels, and both the first transistor M1 and the third transistor M3 are turned off, the pull-up node PU is at the low level, and the third transistor M3 is turned off; at this time, the reset end outputs the high level, both the second transistor M2 and the fourth transistor M4 are turned on, and the output end outputs the low level; and

the shift register unit keeps outputting the low level, until a next frame starts.

The above conventional 4T1C shift register unit is used at a high frequency. As a result, the shift register unit has disadvantages such as poor anti-interference ability, and unstable output signal with a waveform including many large burrs.

### SUMMARY

An object of the present disclosure is to provide a shift register unit, a driving method, a gate driving circuit and a display device, so as to improve the anti-interference ability of the above shift register unit, and reduce both the number and the size of burrs in the output signal and cause the output signal to be more stable for the above shift register unit.

In one aspect, the present disclosure provides in some embodiments shift register unit, including: a gate driving signal output end; a clock signal input end; an input end, wherein an input signal is capable of being applied to the input end; a reset end, wherein a reset signal is capable of being applied to the reset end; a pull-up transistor, wherein a gate electrode of the pull-up transistor is connected to a pull-up node, a first electrode of the pull-up transistor is connected to the clock signal input end, and a second electrode of the pull-up transistor is connected to the gate driving signal output end; a storage capacitor, wherein a first end of the storage capacitor is connected to the pull-up node, and a first low level is applied to a second end of the storage capacitor; an output noise reduction transistor, wherein a gate electrode of the output noise reduction transistor is connected to a pull-down node, a first electrode of the output noise reduction transistor is connected to the gate driving signal output end, and the first low level is applied to a second electrode of the output noise reduction transistor; a pull-down node control module that is connected to the pull-up node and the pull-down node, and configured to apply the first low level or a first high level to the pull-down node under the control of the pull-up node; a pull-up node control module that is connected to the input end, the reset end, the pull-up node, a second high level and a second low level respectively, and configured to apply or not apply the second high level to the pull-up node under the control of the input signal and apply or not apply the second low level to the pull-up node under the control of the reset signal; and a pull-up node noise reduction module, wherein a control end of the pull-up node noise reduction module is connected to the pull-down node, and configured to apply or not apply the first low level to the pull-up node under the control of the pull-down node.

Alternatively, the pull-up node control module includes a first transistor and a second transistor, wherein in the case of performing forward scanning, a gate electrode of the first transistor is connected to the input end, the second high level is applied to a first electrode of the first transistor, and a second electrode of the first transistor is connected to the pull-up node, a gate electrode of the second transistor is connected to the reset end, a first electrode of the second transistor is connected to the pull-up node, and the second low level is applied to a second electrode of the second transistor; and in the case of performing backward scanning, the gate electrode of the first transistor is connected to the reset end, the second low level is applied to the first electrode of the first transistor, the second electrode of the first transistor is connected to the pull-up node, the gate electrode of the second transistor is connected to the input end, the first electrode of the second transistor is connected to the pull-up node, and the second high level is applied to the second electrode of the second transistor.

Alternatively, the pull-up node noise reduction module includes the pull-up node noise reduction module includes a pull-up node noise reduction transistor, wherein the gate electrode of the pull-up node noise reduction transistor is connected to the pull-down node, a first electrode of the pull-up node noise reduction transistor is connected to the pull-up node, and the first low level is applied to a second electrode of the pull-up node noise reduction transistor.

Alternatively, the pull-down node control module is configured to control the pull-down node to be at the first low level in the case that the pull-up node is at the second high level and control the pull-down node to be at the first high level in the case that the pull-up node is at the second low level.

Alternatively, the pull-down node control module includes: a third transistor, wherein the first high level is applied to a gate electrode of the third transistor, the first high level is applied to a first electrode of the third transistor, and a second electrode of the third transistor is connected to the pull-down node; and a fourth transistor, wherein a gate electrode of the fourth transistor is connected to the pull-up node, a first electrode of the fourth transistor is connected to the pull-down node, and the first low level is applied to a second electrode of the fourth transistor.

Alternatively, all of the pull-up transistor, the output noise reduction transistor, the pull-up node noise reduction transistor, the first transistor, the second transistor, the third transistor and the fourth transistor are N-type transistors.

In another aspect, the present disclosure provides in some embodiments a method for driving the above shift register unit, wherein in each display period, the method includes steps of: at a pre-charging stage, applying the high level to the input end, applying the low level to the reset end, applying the low level to the clock signal input end, controlling the pull-up node to be at the second high level by the pull-up node control module, charging the storage capacitor, keeping the pull-up node being at the high level, controlling the pull-up transistor to be turned on, controlling the pull-down node to be at the first low level by the pull-down node control module, so as to control the output noise reduction transistor to be turned off, and control the gate driving signal output end to output the low level; at an output stage, applying the low level to the input end, applying the low level to the reset end, applying the high level to the clock signal input end, keeping the pull-up node being at the high level by the storage capacitor, controlling the pull-up transistor to be turned on, so as to output the high level by the gate driving signal output end, and keeping the pull-down node being at the first low level by the pull-down node control module; at a reset stage, applying the low level to the input end, applying the high level to the reset end, applying the low level to the clock signal input end, controlling the pull-up node to be at the second low level by the pull-up node control module, controlling the pull-down node to be at the first high level by the pull-down node control module, controlling the pull-up node to be at the first low level by the pull-up node noise reduction module to perform noise reduction on the pull-up node, and turning on the output noise reduction transistor to perform noise reduction on the gate driving signal output end, so as to apply the first low level to the gate driving signal output end; and at a constant noise reduction stage, applying the low level to the input end, applying the low level to the reset end, controlling the pull-down node to be at the first high level by the pull-down node control module, controlling the pull-up node to be at the first low level by the pull-up node noise reduction module to perform noise reduction on the pull-up node, turning on the output noise reduction transistor to perform noise reduction on the gate driving signal output end, so as to constantly applying the first low level to the gate driving signal output end.

In yet another aspect, the present disclosure provides in some embodiments a gate driving circuit, which includes multiple levels of above shift register units, wherein the multiple levels of shift register units are arranged on an array substrate; apart from the first-level shift register unit, an input end of a current-level shift register unit is connected to a gate driving signal output end of a previous-level shift register unit; and apart from the last-level shift register unit, a reset end of a current-level shift register unit is connected to a gate driving signal output end of a next-level shift register unit.

Alternatively, a clock signal applied to a clock signal input end of a current-level shift register unit is of a phase reverse to a clock signal applied to a clock signal input end of an adjacent-level shift register unit.

In still yet another aspect, the present disclosure provides in some embodiments a display device, which includes the above gate driving circuit.

Compared with the related arts, in the shift register unit, the driving method, the gate driving circuit and the display device of the present disclosure, the storage capacitor is provided between the pull-up node and the first low level output, so that when the input signal is at the high level, the storage capacitor is charged by the second high level, and the pull-up node is kept at the high level, until the gate driving signal output end outputs the low level. The storage capacitor can function to stabilize the level of the pull-up node PU to improve the anti-interference ability. In the present disclosure, the output noise reduction transistor is used to perform noise reduction on the gate driving signal output end, and the pull-up node noise reduction module performs noise reduction on the pull-up node so as to improve the anti-interference ability of the shift register unit. As a result, the output gate driving signal has fewer blurs and stable waveform. In addition, in embodiments of the present disclosure, the number of transistors included in the shift register unit is reduced, so as to facilitate a design of a slimmer product.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic view showing a circuit of a 4T1C shift register unit in related arts;

FIG. 2 is a timing sequence for the 4T1C shift register unit shown in FIG. 1;

FIG. 3 is a schematic view showing a shift register unit according to some embodiments of the present disclosure;

FIG. 4A is a schematic view showing another shift register unit according to some embodiments of the present disclosure;

FIG. 4B is a schematic view showing another shift register unit according to some embodiments of the present disclosure;

FIG. 5 is a schematic view showing another shift register unit according to some embodiments of the present disclosure;

FIG. 6 is a schematic view showing another shift register unit according to some embodiments of the present disclosure;

FIG. 7 is a schematic view showing a circuit of the shift register unit according to some embodiments of the present disclosure;

FIG. 8 is a timing sequence for the shift register unit shown in FIG. 7 according to some embodiments of the present disclosure; and

FIG. 9 is a schematic view showing a gate driving circuit according to some embodiments of the present disclosure.

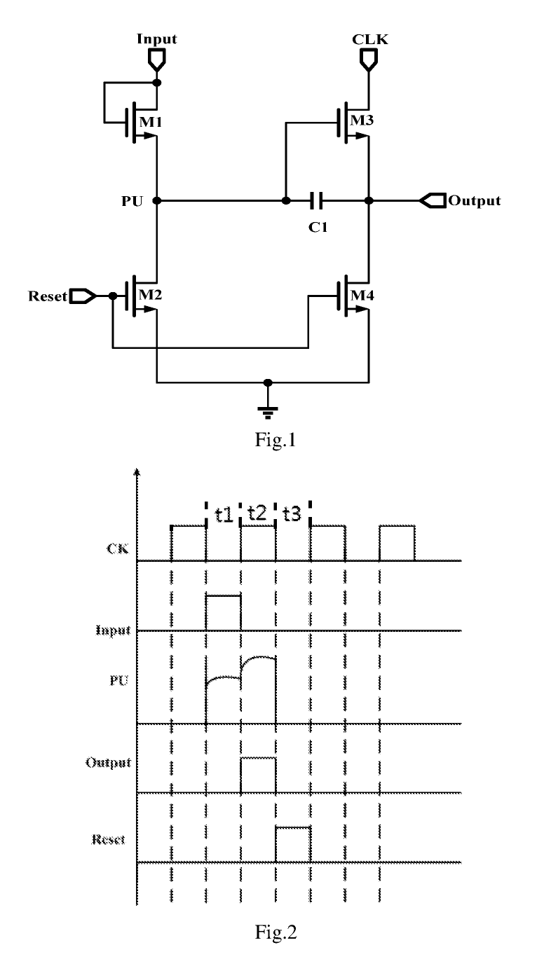

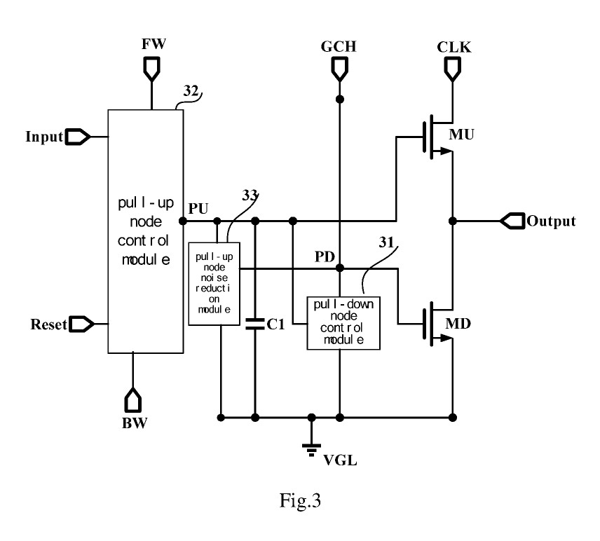

### DETAILED DESCRIPTION

The present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

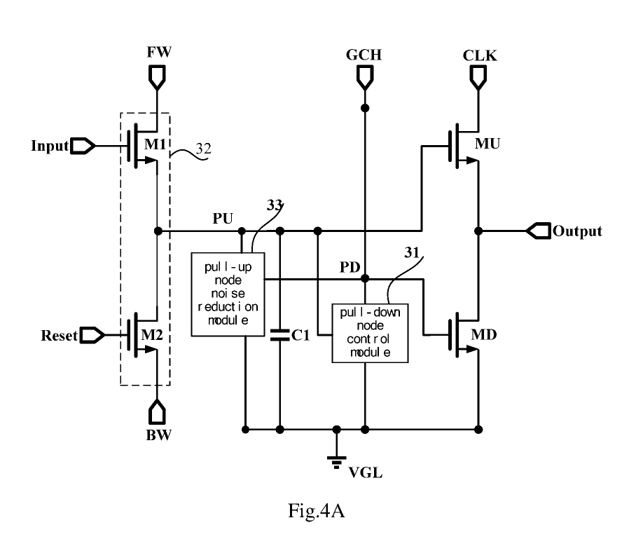

In the embodiments of the present disclosure, as shown in FIG. 3, the shift register unit includes: a gate driving signal output end Output; a clock signal input end CLK; an input end Input, wherein an input signal is capable of being applied to the input end Input; and a reset end Reset, wherein a reset signal is capable of being applied to the reset end Reset. The reset register unit further includes:

a pull-up transistor MU, wherein a gate electrode of the pull-up transistor MU is connected to a pull-up node PU, a first electrode of the pull-up transistor MU is connected to the clock signal input end CLK, and a second electrode of the pull-up transistor MU is connected to the gate driving signal output end Output;

a storage capacitor C1, wherein a first end of the storage capacitor C1 is connected to the pull-up node PU, and a first low level VGL is applied to a second end of the storage capacitor C1;

an output noise reduction transistor MD, wherein a gate electrode of the output noise reduction transistor MD is connected to a pull-down node PD, a first electrode of the output noise reduction transistor MD is connected to the gate driving signal output end Output, and the first low level VGL is applied to a second electrode of the output noise reduction transistor MD;

a pull-down node control module 31 that is connected to the pull-up node PU and the pull-down node PD respectively, and configured to apply the first low level VGL or a first high level GCH to the pull-down node PD under the control of the pull-up node PU;

a pull-up node control module 32 that is connected to the input end Input, the reset end Reset, the pull-up node PU, a second high level FW and a second low level BW respectively, and configured to apply or not apply the second high level FW to the pull-up node PU under the control of the input signal and apply or not apply the second low level BW to the pull-up node PU under the control of the reset signal Reset; and

a pull-up node noise reduction module 33, wherein a control end of the pull-up node noise reduction module is connected to the pull-down node PD, and configured to apply or not apply the first low level VGL to the pull-up node PU under the control of the pull-down node PD.

In the shift register unit according to embodiments of the present disclosure, the storage capacitor is provided between the pull-up node PU and the first low level output end, so that when the input signal is at the high level, the storage capacitor C1 is charged by the second high level FW. The pull-up node PU is kept at the high level, until the gate driving signal output end Output outputs the low level. The storage capacitor C1 can function to stabilize the level of the pull-up node PU to improve the anti-interference ability of the shift register unit. In the present disclosure, the output noise reduction transistor MD is used to perform noise reduction on the gate driving signal output end, and the pull-up node noise reduction module 33 performs noise reduction on the pull-up node PU so as to improve the anti-interference ability of the shift register unit. As a result, the gate driving signal outputted by the shift register unit has fewer blurs and stable waveform.

Alternatively, the pull-up node control module 32 includes a first transistor M1 and a second transistor M2, wherein

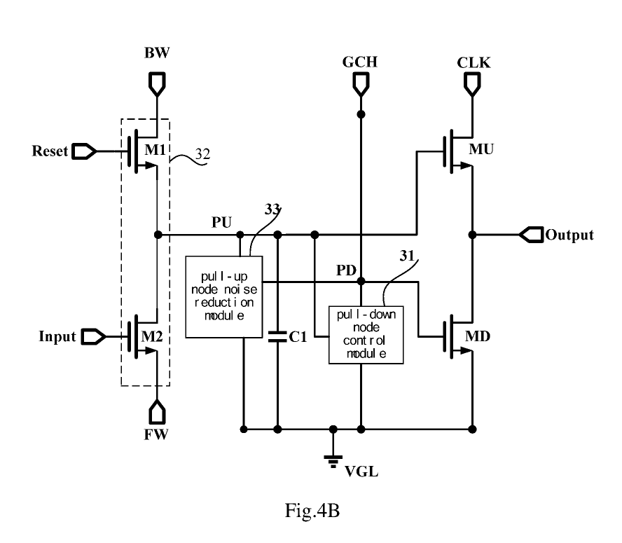

in the case of performing forward scanning, as shown in FIG. 4A, a gate electrode of the first transistor M1 is connected to the input end Input, the second high level FW is applied to a first electrode of the first transistor M1, and a second electrode of the first transistor M1 is connected to the pull-up node PU, a gate electrode of the second transistor M2 is connected to the reset end Reset, a first electrode of the second transistor M2 is connected to the pull-up node PU, and the second low level BW is applied to a second electrode of the second transistor M2; and

in the case of performing backward scanning, as shown in FIG. 4B, the gate electrode of the first transistor M1 is connected to the reset end Reset, the second low level BW is applied to the first electrode of the first transistor M1, the second electrode of the first transistor M1 is connected to the pull-up node PU, the gate electrode of the second transistor M2 is connected to the input end Input, the first electrode of the second transistor M2 is connected to the pull-up node PU, and the second high level FW is applied to the second electrode of the second transistor M2.

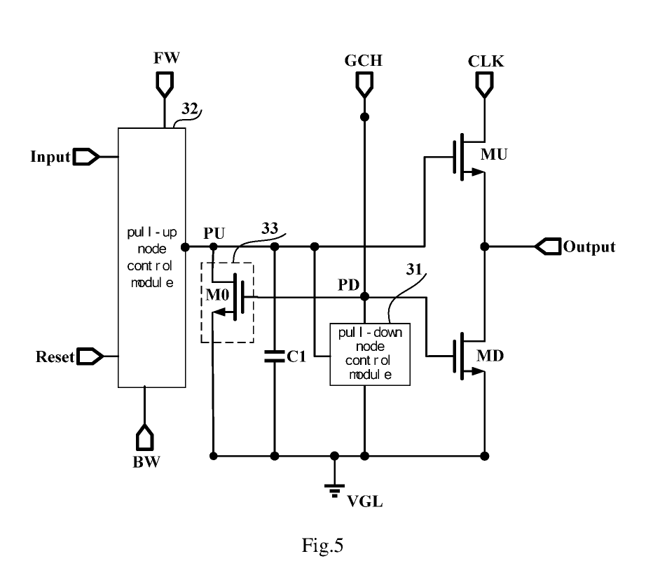

Alternatively, as shown in FIG. 5, the pull-up node noise reduction module 33 includes a pull-up node noise reduction transistor M0, wherein the gate electrode of the pull-up node noise reduction transistor M0 is connected to the pull-down node PD, a first electrode of the pull-up node noise reduction transistor M0 is connected to the pull-up node PU, and the first low level VGL is applied to a second electrode of the pull-up node noise reduction transistor M0.

Alternatively, the pull-down node control module is configured to control the pull-down node to be at the first low level in the case that the pull-up node is at the second high level and control the pull-down node to be at the first high level in the case that the pull-up node is at the second low level.

In the embodiments of the present disclosure, the pull-down node control module included in the shift register unit controls the pull-down node to be at the first high level when the pull-up node is at the second low level, so as to keep the pull-down node being at the first high level after the gate electrode driving signal is outputted. As a result, it enables to constantly perform noise reduction on the gate driving signal output end and the pull-up node.

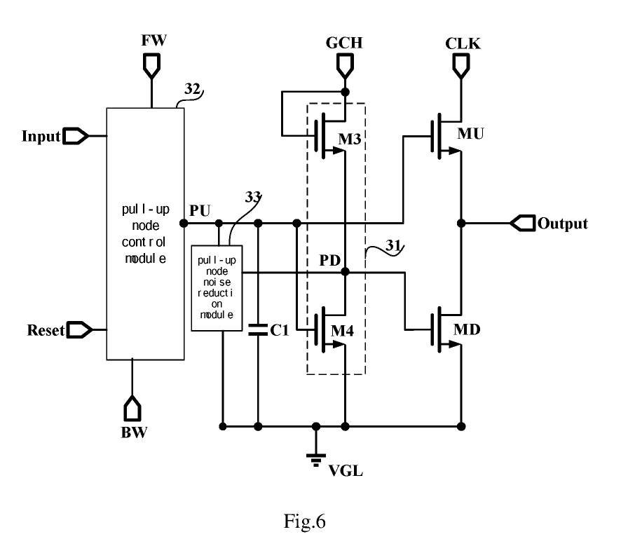

Alternatively, as shown in FIG. 6, the pull-down node control module 31 includes:

a third transistor M3, wherein the first high level GCH is applied to a gate electrode of the third transistor M3, the first high level GCH is applied to a first electrode of the third transistor M3, and a second electrode of the third transistor M3 is connected to the pull-down node PD; and

a fourth transistor M4, wherein a gate electrode of the fourth transistor M4 is connected to the pull-up node PU, a first electrode of the fourth transistor M4 is connected to the pull-down node PD, and the first low level VGL is applied to a second electrode of the fourth transistor M4.

Alternatively, all of the pull-up transistor, the output noise reduction transistor, the pull-up node noise reduction transistor, the first transistor, the second transistor, the third transistor and the fourth transistor are N-type transistors.

In the embodiments of the present disclosure, all of the transistors may be thin film transistors, field effect transistors, or other similar transistors, one of the two electrodes other than the gate electrode of the transistor is called a source electrode, and the other one is called a drain electrode to recognize these two electrodes. Furthermore, based on the characteristics of the transistors, the transistors may be categorized into N-type transistors and P-type transistors. With respect to the driving circuit according to the embodiments of the present disclosure, the explanations are made based on an assumption that all of the transistors are the N-type transistors, and a person skilled in the art may easily implements the embodiments of the present disclosure without any creative work if the P-type transistors are adopted to take the place of the N-type transistors, which also falls within the protection scope of the present disclosure.

In the following embodiments, the shift register unit will be further explained.

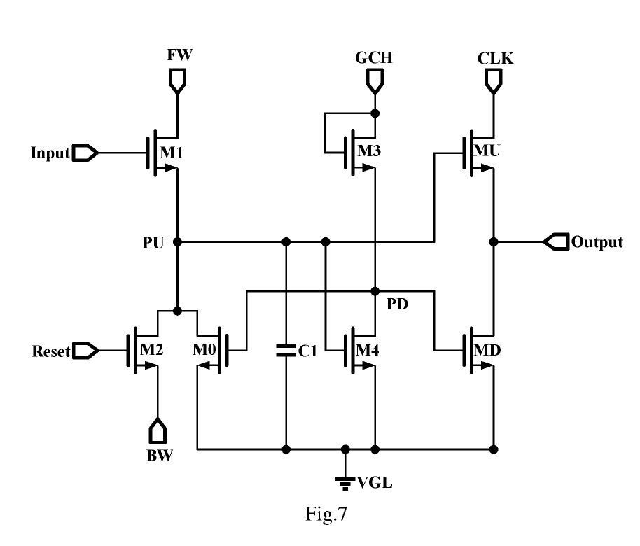

As shown in FIG. 7, the shift register unit of the present disclosure includes: a gate driving signal output end Output; an input end wherein an input signal is capable of being applied to the input end; a reset end Reset, wherein a reset signal is capable of being applied to the reset end Reset; a pull-up transistor MU; a storage capacitor C1; an output noise reduction transistor MD; a pull-down node control module; a pull-up node control module; and a pull-up node noise reduction module.

A gate electrode of the pull-up transistor MU is connected to a pull-up node PU, a first electrode of the pull-up transistor MU is connected to the clock signal input end CLK, and a second electrode of the pull-up transistor MU is connected to the gate driving signal output end Output.

A first end of the storage capacitor C1 is connected to the pull-up node PU, and a first low level VGL is applied to a second end of the storage capacitor C1.

A gate electrode of the output noise reduction transistor MD is connected to a pull-down node PD, a first electrode of the output noise reduction transistor MD is connected to the gate driving signal output end Output, and the first low level VGL is applied to a second electrode of the output noise reduction transistor MD.

The pull-up node noise reduction module includes a pull-up node noise reduction transistor M0, wherein the gate electrode of the pull-up node noise reduction transistor M0 is connected to the pull-down node PD, a first electrode of the pull-up node noise reduction transistor M0 is connected to the pull-up node PU, and the first low level VGL is applied to a second electrode of the pull-up node noise reduction transistor M0.

The pull-up node control module includes:

a first transistor first transistor M1, wherein a gate electrode of the first transistor M1 is connected to the input end Input, the second high level FW is applied to a first electrode of the first transistor M1, and a second electrode of the first transistor M1 is connected to the pull-up node PU; and

a second transistor M2, wherein a gate electrode of the second transistor M2 is connected to the reset end Reset, a first electrode of the second transistor M2 is connected to the pull-up node PU, and the second low level BW is applied to a second electrode of the second transistor M2.

The pull-down node control module includes:

a third transistor M3, wherein the first high level GCH is applied to a gate electrode of the third transistor M3, the first high level GCH is applied to a first electrode of the third transistor M3, and a second electrode of the third transistor M3 is connected to the pull-down node PD; and

a fourth transistor M4, wherein a gate electrode of the fourth transistor M4 is connected to the pull-up node PU, a first electrode of the fourth transistor M4 is connected to the pull-down node PD, and the first low level VGL is applied to a second electrode of the fourth transistor M4.

In FIG. 7, all the transistors are N-type transistors.

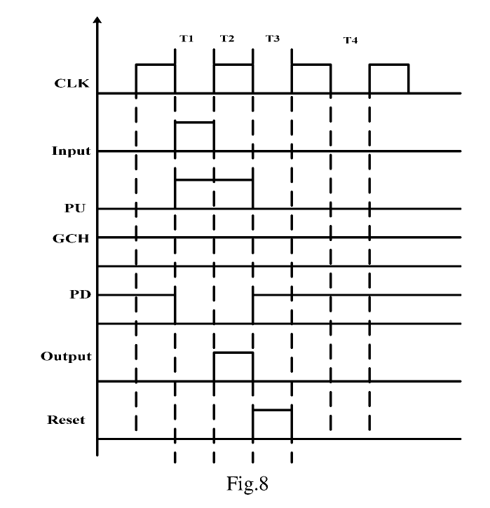

FIG. 8 is a timing sequence for the shift register unit shown in FIG. 7 according to some embodiments of the present disclosure. As shown in FIG. 8, when the exemplary shift register unit shown in FIG. 7 is operating,

at an input stage T1, the low level is applied to the clock signal input CLK, the input signal outputted by the input end Input is at the high level, and the transistor M1 is turned on, so as to pull up the level of the pull-up node PU, the level of the pull-up node PU is kept at the high level until the output end Output outputs the low level, the storage capacitor C1 functions to stabilize the level of the pull-up node PU, so as to improve the anti-interference ability of the above shift register unit, and the pull-up transistor MU is turned on; however, since the CLK is at the low level, the output end Output outputs the low level, and fourth transistor M4 is turned on, so that the level of the pull-down node PD is pulled down to be the first low level VGL, and both the output noise reduction transistor MD and the pull-up node noise reduction transistor M0 are turned off;

at the output stage T2, the high level is applied to the clock signal input end CLK, the level of the pull-up node PU is kept being at the high level, the pull-up transistor MU continues to be turned on, the output end Output outputs the high level, the fourth transistor M4 is turned on, so as to keep the level of the PD being pulled down to be the first low level VGL, and the output noise reduction transistor MD and the pull-up node noise reduction transistor M0 are turned off,

at the reset stage T3, the CLK is at the low level, the reset signal outputted by the reset end Reset is at the high level, the second transistor M2 is turned on, so that the level of the pull-up node PU is pulled down to be the second low level BW; at this time, the fourth transistor M4 is turned off and the third transistor M3 is turned on, so that the level of the pull-down node PD is pulled up to be the first high level GCH; and

at a constant noise reduction stage T4 (i.e. a period between an ending of the reset stage T3 and a starting of a next frame), the pull-up node PU is at the second low level BW, and the pull-down node PD is kept at the first high level GCH so as to constantly perform noise reduction on the gate driving signal output end and the pull-up node; the gate driving signal output end Output outputs the first low level VGL, so that the output noise reduction transistor MD is turned on to perform noise reduction on the gate driving signal output end Output, and the pull-up node noise reduction transistor M0 is turned on to perform noise reduction on the pull-up node PU. As a result, the gate driving signal outputted by the shift register unit has fewer blurs and stable waveform.

In addition, in embodiments of the present disclosure, the number of transistors included in the shift register unit is reduced, so as to facilitate a design of a slimmer product.

The present disclosure provides in some embodiments a method for driving the shift register unit according to claim 1, wherein in each display period, the method includes steps of:

at a pre-charging stage, applying the high level to the input end, applying the low level to the reset end, applying the low level to the clock signal input end, controlling the pull-up node to be at the second high level by the pull-up node control module, charging the storage capacitor, keeping the pull-up node being at the high level, controlling the pull-up transistor to be turned on, controlling the pull-down node to be at the first low level by the pull-down node control module, so as to control the output noise reduction transistor to be turned off, and control the gate driving signal output end to output the low level;

at an output stage, applying the low level to the input end, applying the low level to the reset end, applying the high level to the clock signal input end, keeping the pull-up node being at the high level by the storage capacitor, controlling the pull-up transistor to be turned on, so as to output the high level by the gate driving signal output end, and keeping the pull-down node being at the first low level by the pull-down node control module;

at a reset stage, applying the low level to the input end, applying the high level to the reset end, applying the low level to the clock signal input end, controlling the pull-up node to be at the second low level by the pull-up node control module, controlling the pull-down node to be at the first high level by the pull-down node control module, controlling the pull-up node to be at the first low level by the pull-up node noise reduction module to perform noise reduction on the pull-up node, and turning on the output noise reduction transistor to perform noise reduction on the gate driving signal output end, so as to apply the first low level to the gate driving signal output end; and

at a constant noise reduction stage, applying the low level to the input end, applying the low level to the reset end, controlling the pull-down node to be at the first high level by the pull-down node control module, controlling the pull-up node to be at the first low level by the pull-up node noise reduction module to perform noise reduction on the pull-up node, turning on the output noise reduction transistor to perform noise reduction on the gate driving signal output end, so as to constantly applying the first low level to the gate driving signal output end.

In the method for driving the shift register unit in embodiments of the present disclosure, the storage capacitor is used to stabilize the level of the pull-up node, the output noise reduction transistor is used to perform noise reduction on the gate driving signal output end, and the pull-up node noise reduction module performs noise reduction on the pull-up node so as to improve the anti-interference ability of the shift register unit. As a result, the output gate driving signal has fewer blurs and stable waveform.

The present disclosure provides in some embodiments a gate driving circuit, including multiple levels of the above shift register units arranged on an array substrate,

apart from the first-level shift register unit, an input end of a current-level shift register unit is connected to a gate driving signal output end of a previous-level shift register unit; and

apart from the last-level shift register unit, a reset end of a current-level shift register unit is connected to a gate driving signal output end of a next-level shift register unit.

Alternatively, a clock signal applied to a clock signal input end of a current-level shift register unit is of a phase reverse to a clock signal applied to a clock signal input end of an adjacent-level shift register unit.

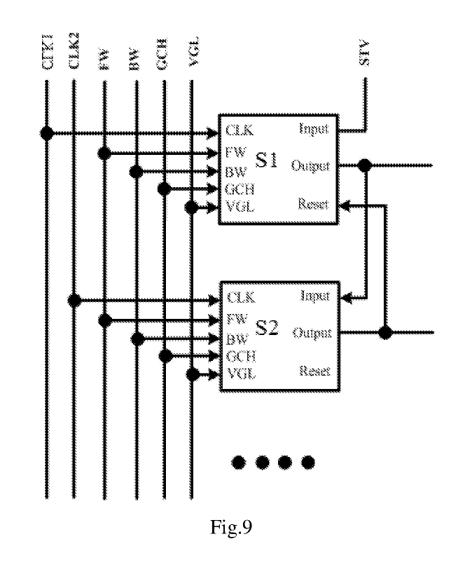

As shown in FIG. 9, in the embodiments of the present disclosure, the gate driving circuit includes multiple levels of the above shift register units arranged on an array substrate. FIG. 9 only shows a first stage of shift register unit S1 and a second stage of shift register unit S2. The first clock signal CLK1 is applied to the clock signal input end CLK of the first stage of shift register unit S1, and the second clock signal CLK2 is applied to the clock signal input end CLK of the second stage of shift register unit S2. The first clock signal CLK1 is of a phase reverse to the second clock signal CLK2. The gate driving signal output end Output of the first stage of shift register unit S1 is connected to the input end Input of the second stage of shift register unit S2. The gate driving signal output end Output of the second stage of shift register unit S2 is connected to the reset end Reset of the first stage of shift register unit S1. A start signal STV is applied to the input end Input of the first stage of shift register unit S1. As shown in FIG. 9, the reference sign “VGL” indicates the first low level, the reference sign “GCH” indicates the first high level, the reference sign “FW” indicates the second high level, and the reference sign “BW” indicates the second low level.

The present disclosure provides in some embodiments a display device including the above gate driving circuit.

The above are merely the preferred embodiments of the present disclosure. A person skilled in the art may make further modifications and improvements without departing from the principle/spirit of the present disclosure, and these modifications and improvements shall also fall within the scope of the present disclosure.

What is claimed is:

1. A shift register unit, comprising:
a gate driving signal output end;
a clock signal input end;
an input end, wherein an input signal is capable of being applied to the input end;
a reset end, wherein a reset signal is capable of being applied to the reset end;
a pull-up transistor, wherein a gate electrode of the pull-up transistor is connected to a pull-up node, a first electrode of the pull-up transistor is connected to the clock signal input end, and a second electrode of the pull-up transistor is connected to the gate driving signal output end;
a storage capacitor, wherein a first end of the storage capacitor is connected to the pull-up node, and a first low level is applied to a second end of the storage capacitor;
an output noise reduction transistor, wherein a gate electrode of the output noise reduction transistor is connected to a pull-down node, a first electrode of the output noise reduction transistor is connected to the gate driving signal output end, and the first low level is applied to a second electrode of the output noise reduction transistor;
a pull-down node control module that is connected to the pull-up node and the pull-down node, and configured to apply the first low level or a first high level to the pull-down node under the control of the pull-up node;
a pull-up node control module that is connected to the input end, the reset end, the pull-up node, a second high level and a second low level, and configured to apply or not apply the second high level to the pull-up node under the control of the input signal and apply or not apply the second low level to the pull-up node under the control of the reset signal; and
a pull-up node noise reduction module, wherein a control end of the pull-up node noise reduction module is connected to the pull-down node, and configured to apply or not apply the first low level to the pull-up node under the control of the pull-down node.

2. The shift register unit according to claim 1, wherein the pull-up node control module comprises a first transistor and a second transistor, wherein
in the case of performing forward scanning, a gate electrode of the first transistor is connected to the input end, the second high level is applied to a first electrode of the first transistor, a second electrode of the first transistor is connected to the pull-up node, a gate electrode of the second transistor is connected to the reset end, a first electrode of the second transistor is connected to the pull-up node, and the second low level is applied to a second electrode of the second transistor; and
in the case of performing backward scanning, the gate electrode of the first transistor is connected to the reset end, the second low level is applied to the first electrode of the first transistor, the second electrode of the first transistor is connected to the pull-up node, the gate electrode of the second transistor is connected to the input end, the first electrode of the second transistor is connected to the pull-up node, and the second high level is applied to the second electrode of the second transistor.

3. The shift register unit according to claim 1, wherein the pull-up node noise reduction module comprises a pull-up node noise reduction transistor, wherein the gate electrode of the pull-up node noise reduction transistor is connected to the pull-down node, a first electrode of the pull-up node noise reduction transistor is connected to the pull-up node, and the first low level is applied to a second electrode of the pull-up node noise reduction transistor.

4. The shift register unit according to claim 1, wherein the pull-down node control module is configured to control the pull-down node to be at the first low level in the case that the pull-up node is at the second high level and control the pull-down node to be at the first high level in the case that the pull-up node is at the second low level.

5. The shift register unit according to claim 2, wherein the pull-down node control module is configured to control the pull-down node to be at the first low level in the case that the pull-up node is at the second high level and control the pull-down node to be at the first high level in the case that the pull-up node is at the second low level.

6. The shift register unit according to claim 3, wherein the pull-down node control module is configured to control the pull-down node to be at the first low level in the case that the pull-up node is at the second high level and control the pull-down node to be at the first high level in the case that the pull-up node is at the second low level.

7. The shift register unit according to claim 4, wherein the pull-down node control module comprises:
a third transistor, wherein the first high level is applied to a gate electrode of the third transistor, the first high level is applied to a first electrode of the third transistor, and a second electrode of the third transistor is connected to the pull-down node; and
a fourth transistor, wherein a gate electrode of the fourth transistor is connected to the pull-up node, a first electrode of the fourth transistor is connected to the pull-down node, and the first low level is applied to a second electrode of the fourth transistor.

8. The shift register unit according to claim 7, wherein all of the pull-up transistor, the output noise reduction transistor, the pull-up node noise reduction transistor, the first transistor, the second transistor, the third transistor and the fourth transistor are N-type transistors.

9. A method for driving the shift register unit according to claim 1, wherein in each display period, the method comprises steps of:
at a pre-charging stage, applying the high level to the input end, applying the low level to the reset end, applying the low level to the clock signal input end, controlling the pull-up node to be at the second high level by the pull-up node control module, charging the storage capacitor, keeping the pull-up node at the high level, controlling the pull-up transistor to be turned on, controlling the pull-down node to be at the first low level by the pull-down node control module, so as to control the output noise reduction transistor to be turned off, and control the gate driving signal output end to output the low level;
at an output stage, applying the low level to the input end, applying the low level to the reset end, applying the high level to the clock signal input end, keeping the pull-up node at the high level by the storage capacitor, controlling the pull-up transistor to be turned on, so as to output the high level by the gate driving signal output end, and keeping the pull-down node at the first low level by the pull-down node control module;
at a reset stage, applying the low level to the input end, applying the high level to the reset end, applying the low level to the clock signal input end, controlling the pull-up node to be at the second low level by the pull-up node control module, controlling the pull-down node to be at the first high level by the pull-down node control module, controlling the pull-up node to be at the first low level by the pull-up node noise reduction module to perform noise reduction on the pull-up node, and turning on the output noise reduction transistor to perform noise reduction on the gate driving signal output end, so as to apply the first low level to the gate driving signal output end; and
at a constant noise reduction stage, applying the low level to the input end, applying the low level to the reset end, controlling the pull-down node to be at the first high level by the pull-down node control module, controlling the pull-up node to be at the first low level by the pull-up node noise reduction module to perform noise reduction on the pull-up node, turning on the output noise reduction transistor to perform noise reduction on the gate driving signal output end, so as to constantly apply the first low level to the gate driving signal output end.

10. A gate driving circuit, comprising multiple levels of shift register units according to claim 1, wherein the multiple levels of shift register units are arranged on an array substrate,
apart from the first-level shift register unit, an input end of a current-level shift register unit is connected to a gate driving signal output end of a previous-level shift register unit; and
apart from the last-level shift register unit, a reset end of a current-level shift register unit is connected to a gate driving signal output end of a next-level shift register unit.

11. The gate driving circuit according to claim 10, wherein the pull-up node control module comprises a first transistor and a second transistor, wherein
in the case of performing forward scanning, a gate electrode of the first transistor is connected to the input end, the second high level is applied to a first electrode of the first transistor, and a second electrode of the first transistor is connected to the pull-up node, a gate electrode of the second transistor is connected to the reset end, a first electrode of the second transistor is connected to the pull-up node, and the second low level is applied to a second electrode of the second transistor; and
in the case of performing backward scanning, the gate electrode of the first transistor is connected to the reset end, the second low level is applied to the first electrode of the first transistor, the second electrode of the first transistor is connected to the pull-up node, the gate electrode of the second transistor is connected to the input end, the first electrode of the second transistor is connected to the pull-up node, and the second high level is applied to the second electrode of the second transistor.

12. The gate driving circuit according to claim 10, wherein the pull-up node noise reduction module comprises a pull-up node noise reduction transistor, wherein the gate electrode of the pull-up node noise reduction transistor is connected to the pull-down node, a first electrode of the pull-up node noise reduction transistor is connected to the pull-up node, and the first low level is applied to a second electrode of the pull-up node noise reduction transistor.

13. The gate driving circuit according to claim 10, wherein the pull-down node control module is configured to control the pull-down node to be at the first low level in the case that the pull-up node is at the second high level and control the pull-down node to be at the first high level in the case that the pull-up node is at the second low level.

14. The gate driving circuit according to claim 11, wherein the pull-down node control module is configured to control the pull-down node to be at the first low level in the case that the pull-up node is at the second high level and control the pull-down node to be at the first high level in the case that the pull-up node is at the second low level.

15. The gate driving circuit according to claim 12, wherein the pull-down node control module is configured to control the pull-down node to be at the first low level in the case that the pull-up node is at the second high level and control the pull-down node to be at the first high level in the case that the pull-up node is at the second low level.

16. The gate driving circuit according to claim 13, wherein the pull-down node control module comprises
a third transistor, wherein the first high level is applied to a gate electrode of the third transistor, the first high level is applied to a first electrode of the third transistor, and a second electrode of the third transistor is connected to the pull-down node; and
a fourth transistor, wherein a gate electrode of the fourth transistor is connected to the pull-up node, a first electrode of the fourth transistor is connected to the pull-down node, and the first low level is applied to a second electrode of the fourth transistor.

17. The gate driving circuit according to claim 16, wherein all of the pull-up transistor, the output noise reduction transistor, the pull-up node noise reduction transistor, the first transistor, the second transistor, the third transistor and the fourth transistor are N-type transistors.

18. The gate driving circuit according to claim 16, wherein a clock signal applied to a clock signal input end of a current-level shift register unit is of a phase reverse to a clock signal applied to a clock signal input end of an adjacent-level shift register unit.

19. A display device comprising the gate driving circuit according to claim 10.

20. The display device according to claim 19, wherein a clock signal applied to a clock signal input end of a current-level shift register unit is of a phase reverse to a clock signal applied to a clock signal input end of an adjacent-level shift register unit.
